(19) United States
(12) Patent Application Publication
(10) Pub. No.: US 2026/0103803 A1
(43) Pub. Date: Apr. 16, 2026

(54) MULTIFUNCTIONAL ETCHING NOZZLE FOR ADDITIVE MANUFACTURING

(71) Applicant: ATLANT 3D. ApS, Taastrup (DE)

(72) Inventors: Samir Hassan Mahmoud Ahmed Sadek, Taastrup (DK); Mira Baraket, Albertslund (DK); Maksym Plakhotnyuk, Kongens Lyngby (DK)

(21) Appl. No.: 18/997,490

(22) PCT Filed: Oct. 16, 2024
(86) PCT No.: PCT/US2024/051594

§ 371 Date: Jan. 21, 2025

(51) Int. Cl. C23C 16/455; B33Y 10/00; B33Y 30/00

(52) U.S. Cl. CPC C23C 16/45563; B33Y 10/00; B33Y 30/00

(57) ABSTRACT

The disclosure relates to devices, systems and methods for selectably etching multi-layer films. Specifically, the disclosure relates to devices, systems and methods for selectably removing layers at the atomic level using a multifunctional nozzle, enabling materials removal using Atomic Layer Etching (ALEt), and Chemical Vapor Etching (CVE), both within the same system.

### BACKGROUND

The disclosure is directed to devices, systems and methods for selectably etching multi-layer films. Specifically, the disclosure is directed to devices, systems and methods for selectably removing layers at the atomic level using a multifunctional nozzle, enabling materials removal using Atomic Layer Etching (ALEt), and Chemical Vapor Etching (CVEt), both within the same system.

In the field of semiconductor technology and materials science, precise control over material removal at the atomic level has become imperative due to the ever-existing need for miniaturization. Atomic Layer Etching (ALEt), and Chemical Vapor Etching (CVEt) have emerged as viable technologies, with ALEt offering unrivaled precision and selectivity in the removal of thin films and nanoscale structures, while CVEt offers certain advantages in terms of speed, simplicity, and versatility for applications where atomic-level precision is not the primary requirement.

Furthermore, while there are similarities between CVEt and ALEt nozzles in terms of material and some design considerations, CVEt nozzles typically have larger diameters, emphasize uniform gas distribution, and cater to continuous gas flow requirements at higher flowrates, while additionally accommodating a broader range of chemistries of surface modifiers while ALEt allows atomic lateral resolution of etching precision.

Achieving uniform gas flow (ligands, surface modifiers and the like reactants) and deposition across the entire desired substrate surface using traditional ALEt and/or CVEt methods and equipment can be challenging. Nevertheless, variations in nozzle design, gas diffusion behavior, the physical state of the material, or gas distribution across the substrate can result in uneven deposition, leading to thickness variations or other issues, resulting in inconsistent performance of the final product. Achieving high uniformity is an important factor for many ALEt and/or CVEt applications.

Other issues associated with traditional ALEt and CVEt nozzle design are, for example; slow process speeds, limited material compatibility, complex process integration, waste of the surface modifier (reducing process efficiency, increasing costs, inconsistent self-limiting of the reaction), scalability (the scale-up from benchtop to commercial applications), compatibility (with various surface modifiers and/or ligands/reactants chemistries), and cost (commercially feasible).

To provide versatility, and cost effectiveness, there is therefore a need for a single system for enabling the formation of multi-layered films using ALEt and CVEt.

### SUMMARY

Disclosed, in various exemplary implementations, are devices, systems and methods for selectably etching multi-layer films. Specifically, the disclosure is directed to devices, systems and methods for selectably removing layers at the atomic level using a multifunctional nozzle, enabling materials removal using Atomic Layer Etching (ALEt), and Chemical Vapor Etching (CVEt), both within the same system.

In an exemplary implementation provided herein is a multifunctional nozzle operable for Atomic Layer Etching (ALEt), and Chemical Vapor Etching (CVEt) the nozzle comprising: an upper housing portion having an apical side and a basal side; a lower housing portion, extending basally from basal side of the upper portion, the lower housing portion having a basal surface, wherein the basal potion defining a peripheral wall having a predetermined perimeter cross section extending basally beyond the basal surface; an inlet port for a first surface modifier, the inlet port for the first surface modifier being in fluid communication with: a first surface modifier reservoir containing the first surface modifier; and the basal surface of the lower housing portion; a first exhaust port, or a first vacuum port, the first vacuum port being in fluid communication with: a first vacuum source; and the basal surface of the lower housing portion a reactant, or a ligand inlet port, the inlet port for the reactant or the ligand being in fluid communication with: a reactant reservoir, or a ligand reservoir containing the reactant, or the ligand; and the basal surface of the lower housing portion; a second exhaust port, or a second vacuum port, the second vacuum port being in fluid communication with: a second vacuum source; and the basal surface of the lower housing portion; and an inert gas inlet port, the inert gas inlet port being in fluid communication with: an inert gas reservoir; and the basal surface of the lower housing portion.

In another exemplary implementation, provided herein is a method of performing an Atomic Layer Etching (ALEt), implemented using the nozzles disclosed herein, the method comprising: Coupling the nozzle to a substrate forming a sealed reaction chamber; Using the first surface modifier port, contacting the reaction chamber with the first surface modifier in a gaseous, vapor, or plasma state, for a predetermined period, wherein the first surface modifier is configured to adhere to the substrate, forming a first modified surface layer; Using the inert gas port, flushing the reaction chamber with the inert gas; Using the first exhaust port, or the first vacuum port, purging the reaction chamber from excess first surface modifier; Using the port for the first reactant, or the port for the first ligand, contacting the reaction chamber with the reactant, or the ligand, each in a gaseous, or vapor state, for a predetermined period, wherein the reactant is configured to react with the modified surface layer, forming a first reaction layer; Using the inert gas port, flushing the reaction chamber; Using the second exhaust port, or the second vacuum port, purging the reaction chamber thereby removing the first modified surface layer; optionally repeating the steps from the step of contacting the reaction chamber with the first surface modifier, to the step of purging the reaction chamber from excess reactant; optionally heating the reaction chamber and decoupling the etched substrate from the nozzle.

In yet another exemplary implementation, provided herein is a method of performing a Chemical Vapor Etching (CVE), implemented using the nozzles disclosed, the method comprising: Coupling the nozzle to a substrate forming a sealed reaction chamber; Using the first surface modifier port, contacting the reaction chamber with the first surface modifier in a gaseous, or vapor state, for a predetermined period; Using the port for the first reactant, or the port for the first ligand, simultaneously with the step of contacting the reaction chamber with the first surface modifier, contacting the reaction chamber with the reactant in a gaseous, or vapor state, for the same predetermined period, wherein the reactant is configured to react with the first surface modifier, adhering to the substrate and forming a first reaction layer; Using the inert gas port, flushing the reaction chamber; Using the first exhaust port, or the first vacuum port, purging the reaction chamber from excess first surface modifier; Using the second exhaust port, or the second vacuum port, simultaneously with the step of purging the reaction chamber from excess first surface modifier purging the reaction chamber from excess reactant, thereby etching the first reaction layer; optionally repeating the steps from the step of contacting the reaction chamber with the first surface modifier, to the step of purging the reaction chamber from excess reactant; and decoupling the substrate from the nozzle.

These and other features of the systems and methods for forming multi-layered film using a multifunctional (multi-purpose) nozzle, enabling precise etching using ALEt and CVE, will become apparent from the following detailed description when read in conjunction with the figures and examples, which are exemplary, not limiting.

### BRIEF DESCRIPTION OF THE FIGURES

For a better understanding of the devices, systems and methods for selectably etching multi-layer films using a multifunctional (multi-purpose) nozzle, enabling etching using ALEt and CVE, with regard to the exemplary implementations thereof, reference is made to the accompanying examples and figures, in which:

FIG. 1A illustrates a top perspective view of the multifunctional (interchangeable with multi-purpose) nozzle, with FIG. 1B, illustrating a bottom perspective thereof;

FIG. 2, illustrates a X-Z cross section C-C of the exemplary implementation illustrated in FIG. 1A;

FIG. 3A, illustrates a X-Z cross section A-A of the exemplary implementation illustrated in FIG. 1A, with FIG. 3B illustrating a X-Z cross section B-B of the exemplary implementation illustrated in FIG. 1A;

FIG. 4, is a schematic illustrating an exemplary implementation of the system, including selectable delivery of surface modifiers, as well as selectable delivery of reactants/ligands;

FIG. 5A, illustrates a first exemplary implementation of ALEt operation, with FIG. 5B illustrating an exemplary implementation of CVEt operation;

FIG. 6, is a schematic illustration of the nozzle coupled to a substrate; and

FIG. 7A-7C, illustrate exemplary implementations of the predetermined perimeter cross section in the peripheral wall of the lower housing portion of the multi-purpose nozzle.

### DETAILED DESCRIPTION

Provided herein are exemplary implementations of devices, systems and methods for etching multi-layered film using a multifunctional (multi-purpose) nozzle, enabling materials Etching using Atomic Layer Etching (ALEt), and Chemical Vapor Etching (CVD), all within the same system.

The static nozzle disclosed provides atomic-scale precision, enabling the removal of single atomic layers, exceptional selectivity for intricate material patterning, minimal damage to substrates, superior uniformity and precise etch depth control. Additionally, the nozzles disclosed herein provide a localized etching enabling precision patterning allowing conformal etching of complex 3D structures, which are valuable for fabricating nanostructures and devices.

Atomic Layer Etching (ALEt) refers to a precise a highly controlled layer-by-layer removal of material. Typically, an initial substrate (e.g., a wafer, an integrated circuit) serves as the foundation, which the surface atomic layer undergoes modification through a self-limiting adsorption reaction, involving either molecular entities or low-energy radicals. Subsequently, this modified surface layer is subjected to interaction with an appropriate ligand or reactant. The function of the ligand (interchangeable with the term “reactant”) is its ability to form bonds with the altered surface atomic layer. This interaction facilitates the etching of the modified surface layer either through the application of elevated temperatures or, additionally or alternatively, by exploiting the condition where the reaction layer of the modified surface with the ligand exhibits a sufficiently low vapor pressure, enabling straightforward extraction from the system via purging and vacuum pumping. The removal process is configured to preclude the decomposition of these substantial molecules, thereby averting any potential for their re-deposition onto the substrate.

In the ALEt disclosed herein, various surface modifiers can be employed to enable precise and selective material removal at the atomic scale. These can be, for example, plasma activation, hydrogen (H₂) activation, chlorine (Cl₂) activation, fluorine (F₂) activation, and oxygen (O₂) activation, which modify the surface chemistry to facilitate subsequent etching steps. Organic ligands and silane-based chemistries can also be used to create tailored surface terminations for selectivity. In exemplary implementations involving metal-containing materials, metal chlorides may serve as surface modifiers. In another exemplary implementation, selection of the first surface modifier depends on the specific materials and desired etching selectivity, referring to the ability of an etching process to preferentially remove one material over another.

Likewise, the ligands and precursors used can be, for example, at least one of: hydrogen fluoride (HF), tetrafluoromethane (CF₄), sulfur hexafluoride (SF₆), nitrogen trifluoride (NF₃), and hexafluoropropylene (C₃F₆). These ligands can react with the surface to introduce fluorine groups, rendering Fluorine-modified surface selectively etchable. The choice of ligand or precursor is contingent upon the specific substrate materials being processed and the desired level of selectivity. In another exemplary implementation, the surface is modified using Chlorine and the ligand is at least one of: hydrogen chloride (HCl), and dichlorosilane (SiH₂Cl₂).

In an exemplary implementation, the substrate is a metal oxide, and the first surface modifier is HF (which is typically, more stable than the metal oxide), while the ligand can be, for example, Sn(acac)₂, or Trimethylaluminum (TMA).

ALEt is done in a controlled, layer-by-layer fashion beginning with a substrate surface (see e.g., 501, FIG. 6) that is chemically prepared, typically cleaned to remove any contaminants or oxides. The surface modification starts with an initial reactant, called the first surface modifier (interchangeable with precursor), being introduced into the reaction chamber (see e.g., 5000, FIG. 6). The first surface modifier is selected based on the substrate composition and properties. It is typically a vapor or gas-phase fluid that can react with, or preferentially adhere to the substrate surface. To achieve atomic-level control, the first surface modifier is introduced into the chamber in a controlled pulse or in brief exposure. The pulses of first surface modifier are precisely timed and controlled to ensure they interact with the substrate surface for a defined period. During this exposure, a self-limiting reaction occurs (meaning that it stops once a full monolayer is formed) at the surface, resulting in the formation of a monolayer or sub-monolayer of the desired modified layer. Excess of the first surface modifier, unreacted byproducts, and any adsorbed impurities are then purged from the chamber using an inert gas such as nitrogen or argon. The subsequent ligand/reactant-exchange is configured to volatilize the modified surface, for example, through a metal-exchange transmetalation reaction between adjacent metal centers, leading to volatile complexes that can be removed and desorbed from the substrate.

The cycle is then repeated, alternating between first surface modifier exposure and ligand/reactant-exchange steps, gradually etching the film layer by layer. The number of cycles is carefully controlled to achieve the desired film thickness, selectivity, and features. Success of ALEt will predicate on the ability to precisely control the number of atomic layers etched during each cycle. This control is achieved by accurately controlling the first surface modifier pulse time, temperature, pressure, and other process parameters. The layer-by-layer etching in ALEt ensures uniformity, even on complex 3D structures such as trenches, pores, or high aspect ratio (>>1) features. The resulting films can be configured to exhibit uniform thickness and excellent control over composition and properties, important in various fields, including semiconductor manufacturing, energy storage, catalysis, optics, and surface engineering.

Additionally, or alternatively, Chemical Vapor Etching (CVE) refers to a technique in which thin films are etched on a substrate through the chemical reaction of vapor-phased, first surface modifiers. In CVE, the process begins with a substrate, (e.g., a wafer), in contact with a reaction chamber (see e.g., 5000, FIG. 6). The chamber is then filled with a carrier gas, often an inert gas like nitrogen or argon, to provide a controlled environment. The substrate is exposed to a pair of reactive gases or vapor-phase reactive chemicals within the chamber. These chemicals chemically react with the material on the substrate surface, leading to the removal or modification of that material. The process typically involves the adsorption of reactants onto the substrate surface, followed by chemical reactions that result in the formation of volatile by-products. These by-products are then removed from the system, leaving behind the desired etched or modified pattern. CVEt can be selective, targeting specific materials while leaving others intact, and it can be used for both isotropic and anisotropic etching, making it a versatile technique in microfabrication and semiconductor device manufacturing. In an exemplary implementation, the precise parameters and reactants used in the CVEt processes disclosed herein, vary depending on the materials and the specific etching requirements. The reactions occurring at the substrate surface can involve a range of processes such as thermal decomposition, pyrolysis, plasma-enhanced reactions, or a combination thereof.

These specific etching requirements can be, for example; precise control over etch rates, e.g., ranging from 10 to 1000 Å/min, to ensure accurate feature depths and dimensions. Selectivity ratios between the target material and underlying layers must be carefully managed, often aiming for ratios exceeding 10:1 to prevent unintended etching. Anisotropy control for creating high-aspect-ratio structures, with sidewall angles approaching 90° for vertical features. Uniformity across the wafer surface, with variations typically sought to be limited to less than 5% to ensure consistent device performance. Likewise, maintain low particulate contamination levels, often below 0.1 particles/cm², and minimize surface roughness to less than 10 Å RMS. Additionally, the CVEt process should be compatible with existing fabrication steps, have minimal impact on underlying layers, and allow for precise endpoint detection to prevent over-etching. These requirements are often interdependent and are carefully balanced to achieve results in the fabrication of advanced integrated circuits.

It should be noted that the exact reaction mechanism in both cases ALEt and CVEt may involve simultaneous deposition and etching reactions. Competition between the growth rate and the etching rate is expected. The exact etching mechanism is dependent on the precise conditions, including temperature, pressure, and gas flow rates, are carefully controlled to drive the desired chemical reactions and etch rate.

### Definitions

In the context of the disclosure, the term “operable” means the system and/or the device and/or the program, or a certain element or step is fully functional, sized, adapted, and calibrated, comprises elements for, and meets applicable operability requirements to perform a recited function when activated, coupled, implemented, actuated, effected, realized, or when an executable program is executed by at least one processor associated with the system and/or the device. In relation to systems and circuits, the term “operable” means the system and/or the circuit is fully functional and calibrated, comprises logic for, having the hardware and firmware necessary, as well as the circuitry for, and meets applicable operability requirements to perform a recited function when executed by at least one processor.

The term “fluid communication” refers to any area, a structure, or communication that allows for fluid communication between at least two fluid retaining regions, for example, a tube, duct, conduit or the like connecting two regions. One or more fluid communication can be configured or adapted to provide for example, vacuum driven flow, electrokinetic driven flow, control the rate and timing of fluid flow by varying the dimensions of the fluid communication passageway, rate of circulation or a combination comprising one or more of the foregoing. Alternatively, and in another exemplary implementation, the term “in communication” can also refer to gaseous and/or vapor communication, i.e. that gas and/or vapor may be transferred from one volume to another volume since these volumes are in communication. This term does not exclude the presence of a gas shutter or valve between the volumes that may be used to interrupt the gas communication between the volumes.

The term “engage” and various forms thereof, when used with reference to retention of a member (e.g., the detent), refer to the application of any forces that tend to hold two components together against inadvertent or undesired separating forces (e.g., such as may be introduced during use of either component). It is to be understood, however, that engagement does not in all cases require an interlocking connection that is maintained against every conceivable type or magnitude of separating force. Also, “engaging element” or “engaging member” refers to one or a plurality of coupled components, at least one of which is configured for releasable engagement.

In the context of the disclosure, the term “accommodate” refers to the ability of an accommodating element (e.g., the peripheral channel) to allow passage or retention of another element (e.g., the O-ring) at close tolerance, without substantial space for other elements or components.

The terms “first,” “second,” and the like, when used herein do not denote any order, quantity, or importance, but rather are used to denote one element from another. The terms “a”, “an” and “the” herein do not denote a limitation of quantity and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the duct(s) includes one or more ducts). Reference throughout the specification to “one exemplary implementation”, “another exemplary implementation”, “an exemplary implementation”, and so forth, means that a particular element (e.g., feature, structure, and/or characteristic) described in connection with the exemplary implementation is included in at least one exemplary implementation described herein, and may or may not be present in other exemplary implementations. In addition, it is to be understood that the described elements may be combined in any suitable manner in the various exemplary implementations.

In addition, for the purposes of the present disclosure, directional or positional terms such as “top”, “apical”, “basal”, “proximal”, “distal”, “bottom”, “upper,” “lower,” “side,” “front,” “frontal,” “forward,” “rear,” “rearward,” “back,” “trailing,” “above,” “below,” “left,” “right,” “radial ,” “vertical,” “upward,” “downward,” “outer,” “inner,” “exterior,” “interior,” “intermediate,” etc., are merely used for convenience in describing the various exemplary implementations of the present disclosure.

The term “coupled”, including its various forms such as “operably coupled”, “coupling” or “couplable”, refers to and comprises any direct or indirect, structural coupling, connection or attachment, or adaptation or capability for such a direct or indirect structural or operational coupling, connection or attachment, including integrally formed components and components which are coupled via or through another component or by the forming process (e.g. an electromagnetic field). Indirect coupling may involve coupling through an intermediary member or adhesive, or abutting and otherwise resting against, whether frictionally (e.g., against a wall) or by separate means without any physical connection.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having”and their derivatives.

All ranges disclosed herein are inclusive of the endpoints, and the endpoints are independently combinable with each other. Furthermore, the terms “first,” “second,” and the like, herein do not denote any order, quantity, or importance, but rather are used to denote one element from another.

Likewise, the term “about” means that amounts, ranges, sizes, formulations, parameters, and other quantities and characteristics are not and do not need be exact, but may be approximate and/or larger or smaller, as desired, reflecting tolerances, conversion factors, rounding off, measurement error and the like, and other factors known to those of skill in the art. In general, an amount, ranges, size, formulation, parameter or other quantity or characteristic is “about” or “approximate” whether or not expressly stated to be such and is intended to include the degree of error associated with measurement of the particular quantity based upon the equipment available at the time of filing the application. For example, “about” can include a range of +/−15% or 10%, or 5% of a given value.

A more complete understanding of the components, processes, assemblies, and devices disclosed herein can be obtained by reference to the accompanying drawings. These figures (also referred to herein as “FIG.”) are merely schematic representations (e.g., illustrations) based on convenience and the ease of demonstrating the present disclosure, and are, therefore, not intended to indicate relative size and dimensions of the devices or components thereof and/or to define or limit the scope of the exemplary implementations. Although specific terms are used in the following description for the sake of clarity, these terms are intended to refer only to the particular structure of the exemplary implementations selected for illustration in the drawings and are not intended to define or limit the scope of the disclosure. In the drawings and the following description below, it is to be understood that like numeric designations refer to components of like function.

Turning to FIG. s 1-3B, and in an exemplary implementation, provided herein is multifunctional nozzle 10 operable for ALEt and CVEt, multi-purpose nozzle 10 comprising: upper housing portion 100 having apical side 101 and basal side 102; lower housing portion 110, extending basally from basal side 102 of upper portion 100, lower housing portion 110 having basal surface 1110, wherein basal potion 110 defining peripheral wall 120 having predetermined perimeter cross section (See e.g., FIG.s 7A-7C) extending basally beyond basal surface 1110; first port 201 for first surface modifier, being in fluid communication with: first surface modifier reservoir (S1, see e.g., FIG. 4) containing first surface modifier; and basal surface 1110 of lower housing portion 110; first exhaust port, or first vacuum port 202, first vacuum port 202 being in fluid communication with: first vacuum source (not shown, e.g, a vacuum pump); and basal surface 1110 of lower housing portion 110; inlet port 203 for first reactant (or first ligand), being in fluid communication with: reactant reservoir (L1, see e.g., FIG. 4), containing first reactant (or first ligand); and basal surface 1110 of lower housing portion 110; second exhaust port, or second vacuum port 204, second vacuum port 204 being in fluid communication with: second vacuum source (not shown, e. g, a vacuum pump); and basal surface 1110 of lower housing portion 110; and inert gas inlet port 205, inert gas inlet port 205 being in fluid communication with: inert gas reservoir (see e.g., FIG. 4); and basal surface 1110 of lower housing portion 110.

As further illustrated, peripheral wall 120 further comprises internal lip 112, and external lip 111, forming channel 113 in-between, channel sized and can be adapted to accommodate optional O-ring 700 (not shown) (not necessary and can be clamped directly to the substrate). As further illustrated in FIG.s 1-3B, multi-purpose nozzle 10, further comprises third vacuum port 210, third vacuum port 210 being in fluid communication with: third vacuum source (not shown, e. g, a vacuum pump); and channel 113 formed in-between internal lip 112 and external lip 111, channel 113 operable to engage a substrate.

Turning now to FIG.s 2-3B, first port 201 for first surface modifier defining basal aperture 2010 is in fluid communication with basal surface 1110 of lower housing portion 110 via plurality of ducts 2012i, branching basally (e.g., a showerhead) from aperture 2010 defined in first port 201 for first surface modifier, each i^{th} duct 2012i terminating in corresponding outlet opening 2013i—defined in basal surface 1110 of lower housing portion 110.

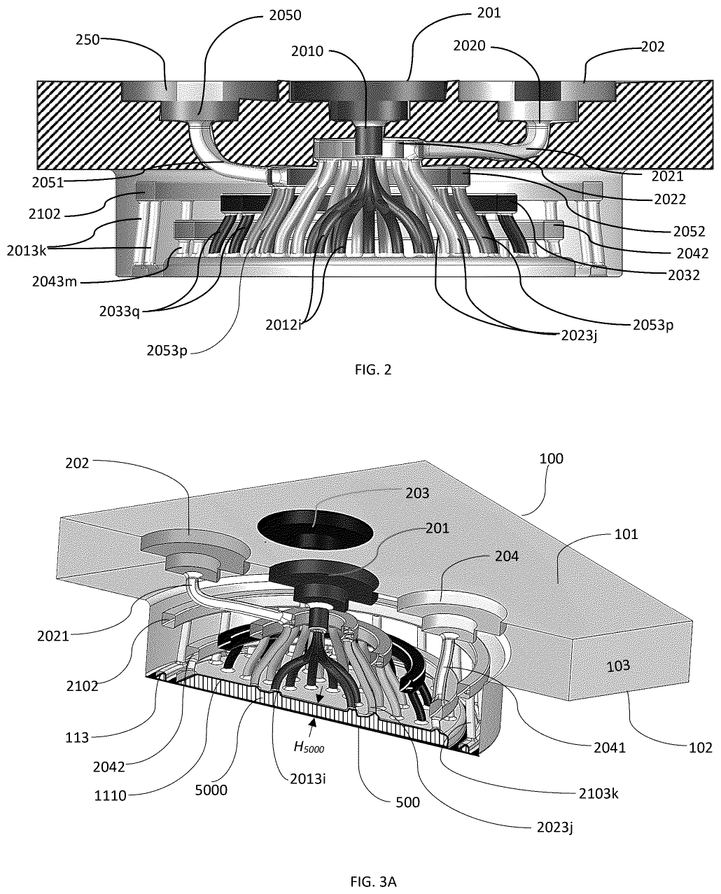

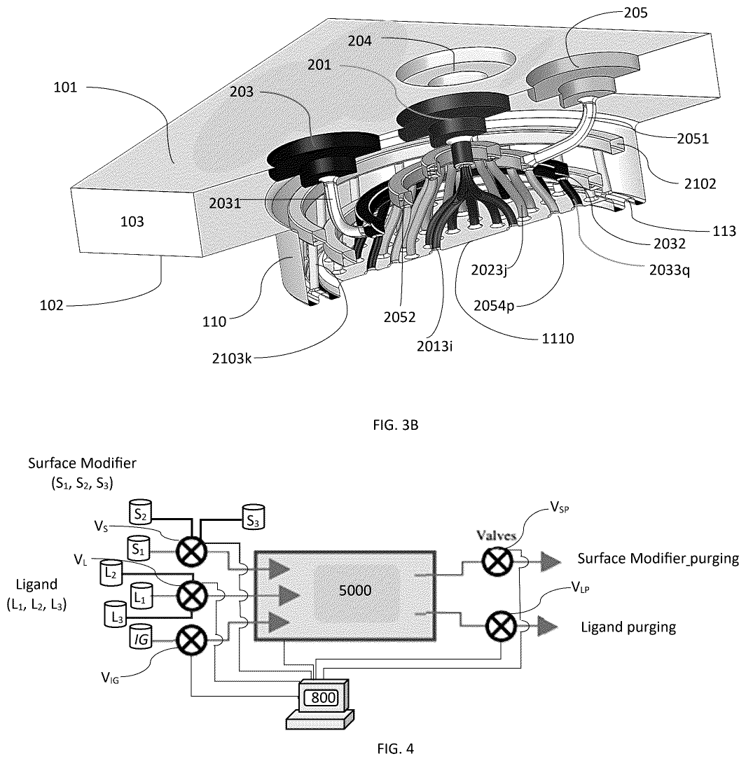

Furthermore, first exhaust port, or first vacuum port 202 is in fluid communication with basal surface 1110 of lower housing portion 110 via: first exhaust tube, or first vacuum tube 2021 extending basally from aperture 2020 defined in first exhaust port, or first vacuum port 202; first annular manifold 2022, in fluid communication with first exhaust tube, or first vacuum tube 2021; and plurality of ducts 2023j extending basally from first annular manifold 2022, each j^{th} duct of plurality of ducts 2023j terminating in a corresponding opening 2024j—defined in the basal surface 1110 of the lower housing portion 110. In an exemplary implementation, first exhaust tube, or first vacuum tube 2021 defines an ovoid cross section having a major axis that is tangential to first annular manifold 2022. Additionally, as illustrated in FIG. 2, and 3B, inlet port 203 for first reactant (or first ligand) is in fluid communication with basal surface 1110 of lower housing portion 110 via: reactant (or ligand) tube 2031 extending basally from aperture 2030 defined in inlet port 203 for first reactant (or first ligand); annular manifold 2032 for first reactant (or first ligand), being in fluid communication with first reactant (or first ligand) tube 2032; and plurality of ducts 2033q extending basally from first reactant (or first ligand) annular manifold 2032, each q^{th} duct of plurality of ducts 2033q terminating in corresponding opening—2034q defined in basal surface 1110 of the lower housing portion 110.

Likewise, as illustrated in FIG. 2, and 3A the second exhaust port, or second vacuum port 204 is in fluid communication with basal surface 1110 of lower housing portion 110 via: second exhaust tube, or second vacuum tube 2041 extending basally from aperture 2040 defined in second exhaust port, or second vacuum port 204; second annular manifold 2042, being in fluid communication with second exhaust tube, or second vacuum tube 2041; and plurality of ducts 2043m extending basally from second annular manifold 2042, each m^{th} duct of plurality of ducts 2043m terminating in corresponding opening 2044m—defined in basal surface 1110 of lower housing portion 110. Moreover, as illustrated in FIG.s 1, 2 , and 3B, inert gas port 205 is in fluid communication with basal surface 1110 of lower housing portion 110 via: inert gas tube 2051 extending basally from aperture 2050 defined in inert gas port 205; inert gas annular manifold 2052, in fluid communication with inert gas tube 2051; and plurality of ducts 2053p extending basally from inert gas annular manifold 2052, each p^{th} duct of plurality of ducts 2053p terminating in corresponding opening 2054p—defined in basal surface 1110 of lower housing portion 110.

As illustrated in FIG. 2, and in an exemplary implementation, the aperture 2010 defined in first port 201 for first surface modifier, first annular manifold 2022, first reactant (or first ligand) annular manifold 2032, second annular manifold 2042, and inert gas manifold 2052 are co-axial, with aperture 2010 defined in first port 201 for first surface modifier being at the center. In another exemplary implementation, third annular manifold 2102 is also co-axial with aperture 2010 defined in first port 201 for first surface modifier. Accordingly and in yet another exemplary implementation, as illustrated in FIG. 2, and 3B, third vacuum port 210 is in fluid communication with channel 113 formed in-between internal lip 112 and external lip 111 via: third vacuum tube 2101 extending basally from aperture 2100 defined in third vacuum port 210; third annular manifold 2102, in fluid communication with third vacuum tube 2101; and plurality of ducts 2103k extending basally from third annular manifold 2102, each k^{th} duct of plurality of ducts 2103k terminating in corresponding opening 2104k—defined apically in channel 113 formed in-between internal lip 112 and external lip 111.

Turning back to FIG. 2, as illustrated, first annular port aperture is defined in upper housing portion 100 of multifunctional nozzle 10, while first reactant (or first ligand) annular manifold 2032, second annular manifold 2042, and inert gas manifold 2052 are each defined in lower housing portion 110. Additionally, and in another exemplary implementation illustrated in FIG.s 2-3B, aperture 2010 defined in first port 201 for first surface modifier, first annular manifold 2022, first reactant (or first ligand) annular manifold 2032, second annular manifold 2042, and inert gas manifold 2052 are axially separated.

Turning now to FIG. 4, illustrating a schematic of the systems disclosed. As illustrated, first surface modifier port 201 is in fluid communication with plurality of selectable first surface modifier reservoirs (S₁, S₂, S₃) via valve V_{S}, while inlet port 203 for first reactant (or first ligand) is in fluid communication with a plurality of selectable reactant reservoirs (L₁, L₂, L₃), via valve V_{L}, and inert gas port 205, via valve V_{IG}. Likewise vacuum, or purge ports 202, and 204 are in fluid communication with a corresponding vacuum source (so as not co-mingle first surface modifiers and first reactant (or first ligand) thus clogging the various conduits), via corresponding purge valves V_{SP} and V_{LP}. As further illustrated, the system further comprises a central control module (CCM) 800, in communication with each of the plurality of plurality of selectable first surface modifier reservoirs (S₁, S₂, S₃), plurality of selectable reactant reservoirs (L₁, L₂, L₃), each of V_{S}, V_{L}, V_{IG}, V_{SP}, V_{LP}, and the various pumps (vacuum, positive displacement, duplex, triplex, peristaltic, and the like), as well as heating elements in communication with the various reservoirs, reaction chamber 5000, are each operable to deliver the various first surface modifiers and reactants into reaction chamber 5000 as either liquid, gas or vapor (or plasma). CCM 800, can be in further communication with substrate 500, operable to control the temperature of substrate 500 via heating elements, chuck and the like. CCM 800 is in further communication with at least one processor, the processor being in communication with a non-transitory storage device, storing thereon a computer-readable medium with a set of executable instructions, configured when executed by the at least one processor to perform the steps of the methods disclosed herein.

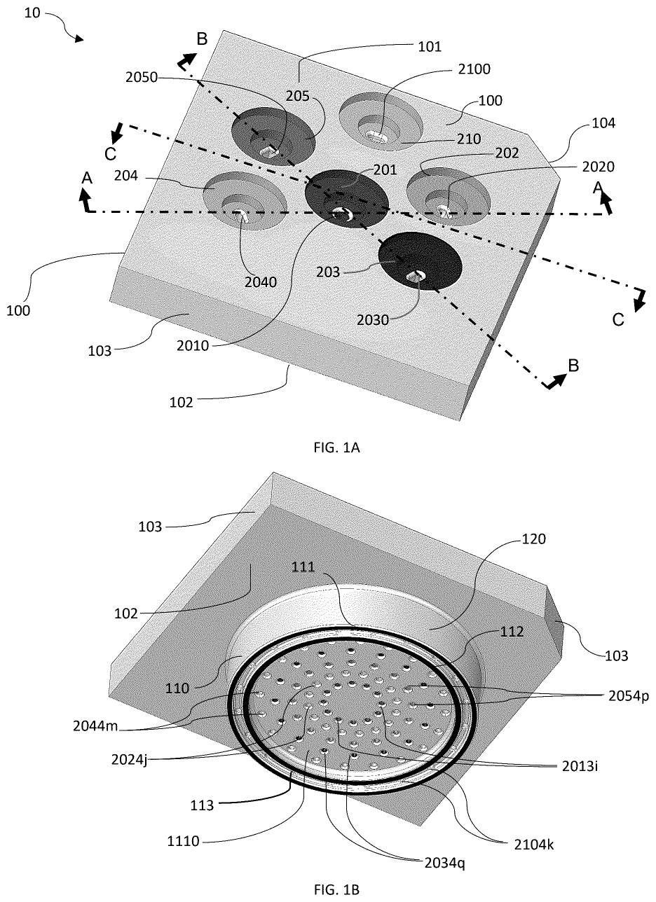

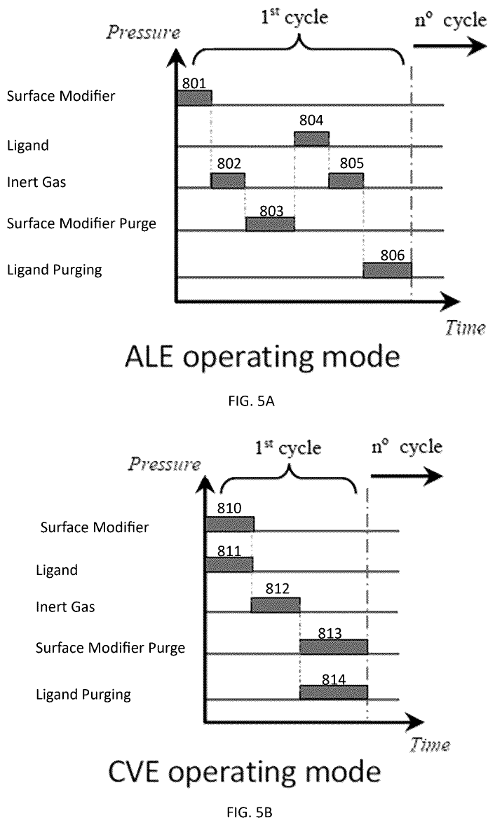

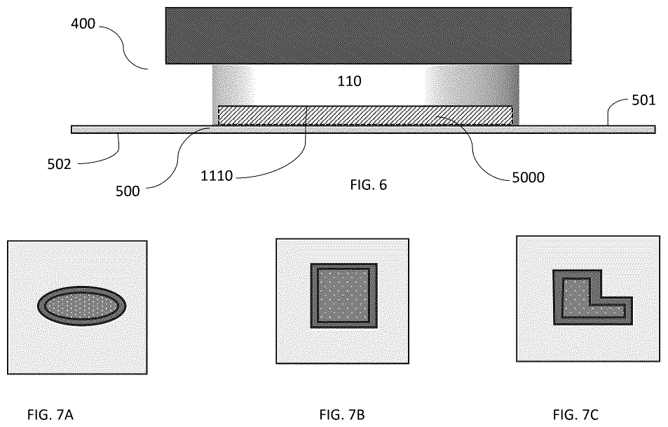

Accordingly, and in an exemplary implementation, illustrated in FIG. 5A, provided herein is a method of performing an Atomic Layer Etching (ALEt), implemented using the multifunctional nozzle disclosed herein, the method comprising: Coupling the multifunctional (or multi-purpose) nozzle to a substrate (see e.g., FIG. 6) forming (hermetically) sealed reaction chamber 5000; Using the first surface modifier port 201, contacting 801 contacting the reaction chamber 5000 with the first surface modifier in a gaseous, vapor, or plasma state, for a predetermined period, wherein the first surface modifier is configured to adhere to the substrate, forming a first modified surface layer; then, using the inert gas port 205, flushing 802 the reaction chamber 5000; and using the firstexhaust port, or the first vacuum port, purging 803 the reaction chamber 5000 from excess first surface modifier. Then, using the first reactant (or first ligand) port 203, contacting 804 the reaction chamber 5000 with the first reactant (or first ligand, again, each in a gaseous, vapor or plasma states), for a predetermined period, wherein the first reactant (or first ligand) is configured to react with the modified surface layer through e.g., ligand-exchange, forming a first reaction layer. Again, using the inert gas port 205, flushing 805 the reaction chamber 5000, and using the second exhaust port, or the second vacuum port 204, purging 806 the reaction chamber from the volatilized ligand-modified surface, thereby removing the first modified surface layer. The cycle can be repeated by optionally repeating the steps from the step of contacting the reaction chamber with the first surface modifier 801, to the step of purging 806 the reaction chamber 5000; and decoupling the substrate 500 from the multifunctional (or multi-purpose) nozzle 10. Coupling of substrate 500 (e.g., a wafer) to multifunctional (or multi-purpose) nozzle 10, can be either done with clamp (see e.g., 400, FIG. 6), optionally in the presence of O-ring disposed in channel 113, or using third vacuum port 210 (See e.g., FIG. 1B). Note that the listed ports and valves can be interchangeable in terms of usage reactant/Vacuum/first surface modifier/. In fact, purging the reaction chamber thereby removing the first modified surface layer, vacuum, first surface modifier and inert gas can be set to flow in any of the listed above conduits. Additionally, the size and shape of the nozzle's communication ports can be modified. These ports can be combined, either forming a cylindrical configuration, or assembled to create a segmented arc, allowing for enhanced versatility in their functionality. It is also noted, that the configuration provided in the drawings, are an exemplary implementation and there are many other configurations possible.

In another exemplary implementation, provided herein is a method of performing a Chemical Vapor Etching (CVE), implemented using the multifunctional (or multi-purpose) nozzle 10 disclosed herein, the method comprising: coupling the multifunctional (or multi-purpose) nozzle 10 to a substrate 500 forming a (hermetically) sealed reaction chamber 5000; then, using the first surface modifier port 201, contacting 810 the reaction chamber 5000 with the first surface modifier in a gaseous, or vapor states, for a predetermined period, wherein the first surface modifier is configured to adhere to the substrate, while simultaneously using the inlet port 203 for first reactant, contacting 811 the sealed reaction chamber 5000 with the reactant in a gaseous, or vapor state—for the same predetermined period, wherein the first reactant is configured to react with the first surface modifier, adhering to the substrate 500 and forming a first reaction layer. Then, using the inert gas port 205, flushing 812 the reaction chamber 5000, and using the first exhaust port, or the first vacuum port 202, purging 813 the reaction chamber 5000 from excess first surface modifier, as well as using the second exhaust port, or the second vacuum port 204, simultaneously with the step of purging 813 the reaction chamber from excess of first surface modifier-purging 814 the reaction chamber 5000 from excess of the first reactant. Here too, optionally repeating the steps from the step of contacting the reaction chamber with the first surface modifier 810, to the step of purging the reaction chamber from excess first surface modifier 813 and first reactant 814; and decoupling the substrate 500 from the multifunctional (or multi-purpose) nozzle. In certain exemplary implementations, the step of coupling the nozzle 10 to a substrate 500 forming the sealed reaction chamber 5000 is preceded by a step of heating the substrate and/or the reaction chamber to a predetermined temperature, followed by a step of flushing the reaction chamber with the inert gas for a predetermined period.

In an exemplary implementation, the first surface modifier, or reactant used in the ALEt, or CVEt the processing methods methods disclosed can be, for example, at least one of: Trimethylaluminum (TMA), Tetrakis(dimethylamino)titanium (TDMAT), Bis(cyclopentadienyl)zirconium(IV) dichloride (Cp₂ZrCl₂), Tetrakis(ethylmethylamino)hafnium (TEMAH), and Bis(ethylcyclopentadienyl)ruthenium(II) (Ru(EtCp)₂), Titanium tetrachloride (TiCl₄), Tungsten hexafluoride (WF₆), Hafnium tetrachloride (HfCl₄), Ruthenium trichloride (RuCl₃), and Molybdenum hexacarbonyl (Mo(CO)₆), Diethyl zinc (DEZ), Dimethylamino magnesium (DMAMg), Bis(cyclopentadienyl)iron(II) (Cp₂Fe), Triisobutylaluminum (TIBA), Tetrakis(trimethylsilyl)hafnium (TTHf), Aluminum isopropoxide (Al(O-iPr)₃), Titanium isopropoxide (Ti(O-iPr)₄), Zirconium n-propoxide (Zr(O-nPr)₄), Hafnium ethoxide (Hf(OEt)₄), Tantalum ethoxide (Ta(OEt)₅), Bis(t-butylamino)silane (BTBAS), Bis(t-butylamino)zinc (BTBAS₂), Bis(t-butylamino)titanium (BTBAT), Bis(t-butylamino)zirconium (BTBZ), Bis(t-butylamino)hafnium (BTBAH), Dimethylcyclopentadienyl platinum (MeCpPtMe₃), Bis(methylcyclopentadienyl)nickel (Ni(MeCp)₂), Cyclopentadienyltungsten tricarbonyl (CpW(CO)₃), Dimethylcyclopentadienyl manganese tricarbonyl (MeCpMn(CO)₃), Iron pentacarbonyl (Fe(CO)₅), Al(CH₃)₃, AlCl(CH₃)₂, Sn(acac)₂, BCl₃, Hhfac, HCOOH, PMe₃, dHF, Ga(CH₃)₃, SiCl₄, TiCl₄ and HCl.

In another exemplary implementation, the inert gas can be at least one of: Nitrogen, Argon, Helium, and Neon. It is noted that the choice of inert gas depends on factors such as process requirements, film properties, equipment capabilities, and cost considerations. Additionally, specific applications or variations within ALEt and CVEt techniques may call for the use of other inert gases or gas mixtures.

In addition, another exemplary implementation, the reactant, coreactant or coreagent in gas or plasma phase can be one or a mixture of: HF, CHF₃, CF₄., H₂, NF₃, XeF₂, BCl₃/Cl₂, C₄H₃F₇O, C₃H₃F₃, HBr, O₂, CF₄/O₂ F₂/He, C₄F₈, CH₃F, Al(CH₃)₃, C₄F₈ plasma, WF₆, BCl₃, SF₄, SO₂Cl₂, and Hacac. It is noted that the choice of reactant depends on factors such as process requirements, film properties, equipment capabilities, and cost considerations. Additionally, specific applications or variations within ALEt and CVEt techniques may call for the use of other reagents or reagent gas mixtures.

Surface treatment of the substrate used in the methods described herein can be at least one of: solvent (e.g., acetone, isopropyl alcohol (IPA), or ultrasonic cleaning to remove organic contaminants and particles) or acid (e.g., sulfuric acid (H₂SO₄) or hydrochloric acid (HCl)), cleaning; plasma (e.g., using reactive gases like oxygen (O₂), hydrogen (H₂), or fluorine-based gases (CF₄, SF₆), is done to remove native oxide layers or to pattern the substrate surface), and/or wet (e.g., to remove unwanted layers or roughen the surface for improved film adhesionfor example, for sequential infiltration synthesis etching; and surface functionalization (e.g., silane coupling agents, such as APTES (aminopropyltriethoxysilane) or HMDS (hexamethyldisilazane), by introducing specific chemical groups that enhance film bonding or modify surface energy).

Surface energy modification is configured to change the surface energy, which is the excess energy present at a material's surface compared to its bulk, typically measured in mJ/m² or dynes/cm. The most common method for measuring surface energy is contact angle measurement, governed by ASTM D7490, which observes the angle formed between a liquid droplet and the solid surface. Other relevant ASTM standards include D2578 for wetting tension of polymer films. These techniques allow for precise quantification of surface energy changes, enabling optimization for specific applications such as improved adhesion, wetting, or coating performance. For example, in semiconductor manufacturing, surface energy modification can enhance film bonding, controlling wettability, and improving the overall quality and reliability of integrated circuits.

Accordingly and in an exemplary implementation, provided herein is a multifunctional nozzle operable for Atomic Layer Etching (ALEt), and Chemical Vapor Etching (CVEt) the nozzle comprising: an upper housing portion having an apical side and a basal side; a lower housing portion, extending basally from basal side of the upper portion, the lower housing portion having a basal surface, wherein the basal potion defining a peripheral wall having a predetermined perimeter cross section extending basally beyond the basal surface; an inlet port for a first surface modifier, the inlet port for the first surface modifier being in fluid communication with: a first surface modifier reservoir containing the first surface modifier; and the basal surface of the lower housing portion; a first exhaust port, or a first vacuum port, the first vacuum port being in fluid communication with: a first vacuum source; and the basal surface of the lower housing portion a reactant, or a ligand inlet port, the inlet port for the reactant or the ligand being in fluid communication with: a reactant reservoir, or a ligand reservoir containing the reactant, or the ligand; and the basal surface of the lower housing portion; a second exhaust port, or a second vacuum port, the second vacuum port being in fluid communication with: a second vacuum source; and the basal surface of the lower housing portion; and an inert gas inlet port, the inert gas inlet port being in fluid communication with: an inert gas reservoir; and the basal surface of the lower housing portion, the nozzle further comprising (i) a third vacuum port, the third vacuum port being in fluid communication with: a third vacuum source; and the channel formed in-between the internal lip and the external lip, (ii) operable to engage a substrate, wherein (iii) the inlet port for the first surface modifier is in fluid communication with the basal surface of the lower housing portion via a plurality of ducts branching basally from an aperture defined in the inlet port for the first surface modifier, each duct terminating in a corresponding outlet opening for the first surface modifier—defined in the basal surface of the lower housing, (iv) the first exhaust port, or the first vacuum port is in fluid communication with the basal surface of the lower housing portion via: a first exhaust tube, or a first vacuum tube extending basally from an aperture defined in the first exhaust port, or the first vacuum port; a first annular manifold, in fluid communication with the first exhaust tube, or the first vacuum tube; and a plurality of ducts extending basally from the first annular manifold, each of the plurality of ducts terminating in a corresponding opening—defined in the basal surface of the lower housing portion, wherein (v) the port for the first reactant, or the port for the first ligand is in fluid communication with the basal surface of the lower housing portion via: a reactant tube, or a ligand tube, each extending basally from an aperture defined in the port for the first reactant, or the port for the first ligand respectively; a reactant annular manifold, or a ligand annular manifold, each being in fluid communication with the reactant tube, or the ligand tube respectively; and a plurality of ducts extending basally from the reactant annular manifold, or the ligand annular manifold, each of the plurality of ducts terminating in a corresponding opening—defined in the basal surface of the lower housing portion, (vi) the second exhaust port, or the second vacuum port is in fluid communication with the basal surface of the lower housing portion via: a second exhaust tube, or a second vacuum tube extending basally from an aperture defined in the second exhaust port, or the second vacuum port; a second annular manifold, in fluid communication with the second exhaust tube, or the second vacuum tube; and a plurality of ducts extending basally from the second annular manifold, each of the plurality of ducts terminating in a corresponding opening—defined in the basal surface of the lower housing portion, wherein (vii) the inert gas port is in fluid communication with the basal surface of the lower housing portion via: an inert gas tube extending basally from an aperture defined in the inert gas port; an inert gas annular manifold, in fluid communication with the inert gas tube; and a plurality of ducts extending basally from the inert gas annular manifold, each of the plurality of ducts terminating in a corresponding opening—defined in the basal surface of the lower housing portion, (viii) the aperture defined in the inlet port for the first surface modifier, the first annular manifold, the reactant annular manifold, or the ligand annular manifold, the second annular manifold, and the inert gas manifold are all co-axial to eachother, wherein (ix) the third vacuum port is in fluid communication with the channel formed in-between the internal lip and the external lip via: a third vacuum tube extending basally from an aperture defined in the third vacuum port; a third annular manifold, in fluid communication with the third vacuum tube; and a plurality of ducts extending basally from the third annular manifold, each of the plurality of ducts terminating in a corresponding opening—defined apically in the channel formed in-between the internal lip and the external lip, (x) the first annular port is in the upper housing portion of the nozzle, wherein (xi) the reactant annular manifold, or the ligand annular manifold, the second annular manifold, and the inert gas manifold are in the lower housing portion, wherein (xii) the aperture defined in the inlet port for the first surface modifier, the first annular manifold, the reactant annular manifold, or the ligand annular manifold, the second annular manifold, and the inert gas manifold are axially separated (in other words, NOT coaxial), wherein (xiii) the first surface modifier port is in fluid communication with a plurality of selectable surface modifier reservoirs (in other words, through e.g., selection valves and check-valves that allow selecting precursor reservoirs without affecting the operation of other components in the system (e.g., inert gasses and reactants)), and similarly wherein (xiv) the port for the first reactant, or the port for the first ligand, is in fluid communication with a plurality of selectable reactant reservoirs and/or ligand reservoirs.

In another exemplary implementation, provided herein is a method of performing an Atomic Layer Etching (ALEt), implemented using the nozzle of any one of claims 1-15, the method comprising: Coupling the nozzle to a substrate forming a sealed reaction chamber, the nozzle having a predetermined perimeter shape; Using the first surface modifier port, contacting the reaction chamber with the first surface modifier in a gaseous, vapor, or plasma state, for a predetermined period, wherein the first surface modifier is configured to adhere to the substrate, forming a first modified surface layer; Using the inert gas port, flushing the reaction chamber with the inert gas; Using the first exhaust port, or the first vacuum port, purging the reaction chamber from excess first surface modifier; Using the port for the first reactant, or the port for the first ligand, contacting the reaction chamber with the reactant, or the ligand, each in a gaseous, or vapor state, for a predetermined period, wherein the reactant is configured to react with the modified surface layer, forming a first reaction layer; Using the inert gas port, flushing the reaction chamber; Using the second exhaust port, or the second vacuum port, purging the reaction chamber thereby removing the first modified surface layer; Repeating the steps from the step of contacting the reaction chamber with the first surface modifier, to the step of purging the reaction chamber from excess reactant; Optionally controlling inert gas valve timing, the first exhaust port, the reactant gas port, and the second exhaust port; and Optionally heating the reaction chamber and decoupling the etched substrate from the nozzle, wherein (xv) the substrate is a wafer, or a wafer disposed on a carrier, (xvi) the step of purging the reaction chamber with the inert gas is preceded by a step of heating the reaction chamber to a predetermined temperature, and wherein (xvi) the nozzle size and inner structure can be scaled to fit the etching process requirements.

In yet another exemplary implementation, provided herein is a method of performing a Chemical Vapor Etching (CVE), implemented using the nozzle of any one of claims 1-15, the method comprising: Coupling the nozzle to a substrate forming a sealed reaction chamber, the nozzle having a predetermined perimeter shape; Using the first surface modifier port, contacting the reaction chamber with the first surface modifier in a gaseous, or vapor state, for a predetermined period; Using the port for the first reactant, or the port for the first ligand, simultaneously with the step of contacting the reaction chamber with the first surface modifier, contacting the reaction chamber with the reactant in a gaseous, or vapor state, for the same predetermined period, wherein the reactant is configured to react with the first surface modifier, adhering to the substrate and forming a first reaction layer; Using the inert gas port, flushing the reaction chamber; Using the first exhaust port, or the first vacuum port, purging the reaction chamber from excess first surface modifier; Using the second exhaust port, or the second vacuum port, simultaneously with the step of purging the reaction chamber from excess first surface modifier—purging the reaction chamber from excess reactant, thereby etching the first reaction layer; Repeating the steps from the step of contacting the reaction chamber with the first surface modifier, to the step of purging the reaction chamber from excess reactant; Optionally controlling inert gas valve timing, the first exhaust port, the reactant gas port, and the second exhaust port; and Decoupling the substrate from the nozzle, wherein (xvii) the substrate is a wafer, or a wafer disposed on a carrier, (xviii) the step of coupling the nozzle to the substrate forming the sealed reaction chamber is preceded by a step of heating the substrate to a predetermined temperature, wherein (xix) the steps of simultaneously contacting the reaction chamber with the first surface modifier and the reactant, is preceded by a step of flushing the reaction chamber with the inert gas for a predetermined period, and wherein (xx) the nozzle size and inner structure can be scaled to fit the etching process requirements.

While in the foregoing specification the devices, systems and methods for selectably removing layers at the atomic level using a multifunctional nozzle, enabling materials removal using Atomic Layer Etching (ALEt), and Chemical Vapor Etching (CVEt), both within the same system, have been described in relation to certain preferred exemplary implementations, and many details are set forth for purpose of illustration, it will be apparent to those skilled in the art that the disclosure is susceptible to additional exemplary implementations and that certain of the details described in this specification and as are more fully delineated in the following claims can be varied considerably without departing from the basic principles of this disclosure.

1. A multifunctional nozzle operable for Atomic Layer Etching (ALEt), and Chemical Vapor Etching (CVEt) the nozzle comprising:
a) an upper housing portion having an apical side and a basal side;
b) a lower housing portion, extending basally from basal side of the upper portion, the lower housing portion having a basal surface, wherein the basal potion defining a peripheral wall having a predetermined perimeter cross section extending basally beyond the basal surface;
c) an inlet port for a first surface modifier, the inlet port for the first surface modifier being in fluid communication with:
i. a first surface modifier reservoir containing the first surface modifier; and
ii. the basal surface of the lower housing portion;
d) a first exhaust port, or a first vacuum port, the first vacuum port being in fluid communication with:
i. a first vacuum source; and
ii. the basal surface of the lower housing portion
e) a reactant, or a ligand inlet port, the inlet port for the reactant or the ligand being in fluid communication with:
i. a reactant reservoir, or a ligand reservoir containing the reactant, or the ligand; and
ii. the basal surface of the lower housing portion;
f) a second exhaust port, or a second vacuum port, the second vacuum port being in fluid communication with:
i. a second vacuum source; and
ii. the basal surface of the lower housing portion; and
g) an inert gas inlet port, the inert gas inlet port being in fluid communication with:
i. an inert gas reservoir; and
ii. the basal surface of the lower housing portion.

2. The nozzle of claim 1, further comprising a third vacuum port, the third vacuum port being in fluid communication with:
a) a third vacuum source; and
b) the channel formed in-between the internal lip and the external lip.

3. The nozzle of claim 1, operable to engage a substrate.

4. The nozzle of claim 1, wherein the inlet port for the first surface modifier is in fluid communication with the basal surface of the lower housing portion via a plurality of ducts branching basally from an aperture defined in the inlet port for the first surface modifier, each duct terminating in a corresponding outlet opening for the first surface modifier—defined in the basal surface of the lower housing.

5. The nozzle of claim 1, wherein the first exhaust port, or the first vacuum port is in fluid communication with the basal surface of the lower housing portion via:
a) a first exhaust tube, or a first vacuum tube extending basally from an aperture defined in the first exhaust port, or the first vacuum port;
b) a first annular manifold, in fluid communication with the first exhaust tube, or the first vacuum tube; and
c) a plurality of ducts extending basally from the first annular manifold, each of the plurality of ducts terminating in a corresponding opening—defined in the basal surface of the lower housing portion.

6. The nozzle of claim 5, wherein the port for the first reactant, or the port for the first ligand is in fluid communication with the basal surface of the lower housing portion via:
a) a reactant tube, or a ligand tube, each extending basally from an aperture defined in the port for the first reactant, or the port for the first ligand respectively;
b) a reactant annular manifold, or a ligand annular manifold, each being in fluid communication with the reactant tube, or the ligand tube respectively; and
c) a plurality of ducts extending basally from the reactant annular manifold, or the ligand annular manifold, each of the plurality of ducts terminating in a corresponding opening defined in the basal surface of the lower housing portion.

7. The nozzle of claim 6, wherein the second exhaust port, or the second vacuum port is in fluid communication with the basal surface of the lower housing portion via:
a) a second exhaust tube, or a second vacuum tube extending basally from an aperture defined in the second exhaust port, or the second vacuum port;
b) a second annular manifold, in fluid communication with the second exhaust tube, or the second vacuum tube; and
c) a plurality of ducts extending basally from the second annular manifold, each of the plurality of ducts terminating in a corresponding opening—defined in the basal surface of the lower housing portion.

8. The nozzle of claim 7, wherein the inert gas port is in fluid communication with the basal surface of the lower housing portion via:
a) an inert gas tube extending basally from an aperture defined in the inert gas port;
b) an inert gas annular manifold, in fluid communication with the inert gas tube; and
c) a plurality of ducts extending basally from the inert gas annular manifold, each of the plurality of ducts terminating in a corresponding opening—defined in the basal surface of the lower housing portion.

9. The nozzle of claim 8, wherein the aperture defined in the inlet port for the first surface modifier, the first annular manifold, the reactant annular manifold, or the ligand annular manifold, the second annular manifold, and the inert gas manifold are co-axial.

10. The nozzle of claim 2, wherein the third vacuum port is in fluid communication with the channel formed in-between the internal lip and the external lip via:
a) a third vacuum tube extending basally from an aperture defined in the third vacuum port;
b) a third annular manifold, in fluid communication with the third vacuum tube; and
c) a plurality of ducts extending basally from the third annular manifold, each of the plurality of ducts terminating in a corresponding opening—defined apically in the channel formed in-between the internal lip and the external lip.

11. The nozzle of claim 10, wherein the first annular port is in the upper housing portion of the nozzle.

12. The nozzle of claim 11, wherein the reactant annular manifold, or the ligand annular manifold, the second annular manifold, and the inert gas manifold are in the lower housing portion.

13. The nozzle of claim 9, wherein the aperture defined in the inlet port for the first surface modifier, the first annular manifold, the reactant annular manifold, or the ligand annular manifold, the second annular manifold, and the inert gas manifold are axially separated.

14. The nozzle of claim 1, wherein the first surface modifier port is in fluid communication with a plurality of selectable surface modifier reservoirs.

15. The nozzle of claim 1, wherein the port for the first reactant, or the port for the first ligand, is in fluid communication with a plurality of selectable reactant reservoirs and/or ligand reservoirs.

16. A Method of performing an Atomic Layer Etching (ALEt), implemented using a multifunctional nozzle operable for Atomic Layer Etching (ALEU), and Chemical Vapor Etching (CVE), the nozzle comprising: an upper housing portion having an apical side and a basal side; a lower housing portion, extending basally from basal side of the upper portion, the lower housing portion having a basal surface, wherein the basal potion defining a peripheral wall having a predetermined perimeter cross section extending basally beyond the basal surface; an infer port for a first surface modifier, the inlet port for the first surface modifier being in fluid communication with; (i) a first surface modifier reservoir containing the first surface modifier, and (ii) the basal surface of the lower housing portion; a first exhaust port, or a first vacuum port, the first vacuum port being in fluid communication with; (i) a first vacuum source; and (i) the basal surface of the lower housing portion; a reactant. or a ligand inlet port, the inlet port for the reactant or the ligand being in fluid communication with; (i) a reactant reservoir, or a ligand reservoir containing the reactant, or the ligand; and (ii) the basal surface of the lower housing portion; a second exhaust port, or a second vacuum port, the second vacuum port being in fluid communication with; (i) a second vacuum source; and (ii) the basal surface of the lower housing portion; and an inert gas inlet port, the inert gas inlet port being in fluid communication with: (i) an inert gas reservoir; and (ii) the basal surface of the lower housing portion, the method comprising:
a) Coupling the nozzle to a substrate forming a sealed reaction chamber, the nozzle having a predetermined perimeter shape;
b) Using the first surface modifier port, contacting the reaction chamber with the first surface modifier in a gaseous, vapor, or plasma state, for a predetermined period, wherein the first surface modifier is configured to adhere to the substrate, forming a first modified surface layer;
c) Using the inert gas port, flushing the reaction chamber with the inert gas;
d) Using the first exhaust port, or the first vacuum port, purging the reaction chamber from excess first surface modifier;
e) Using the port for the first reactant, or the port for the first ligand, contacting the reaction chamber with the reactant, or the ligand, each in a gaseous, or vapor state, for a predetermined period, wherein the reactant is configured to react with the modified surface layer, forming a first reaction layer;
f) Using the inert gas port, flushing the reaction chamber; Using the second exhaust port, or the second vacuum port, purging the reaction chamber thereby removing the first modified surface layer;
g) Repeating the steps from the step of contacting the reaction chamber with the first surface modifier, to the step of purging the reaction chamber from excess reactant;
h) Optionally controlling inert gas valve timing, the first exhaust port, the reactant gas port, and the second exhaust port; and
i) Optionally heating the reaction chamber and decoupling the etched substrate from the nozzle.

17. The method of claim 16, wherein the substrate is a wafer.

18. The method of claim 16, wherein the step of purging the reaction chamber with the inert gas is preceded by a step of heating the reaction chamber to a predetermined temperature.

19. The method of claim 16, where the nozzle size and inner structure is scaled to fit the etching process requirements.

20. A method of performing a Chemical Vapor Etching (CVE), implemented using the nozzle of claim 16, the method comprising:
a) Coupling the nozzle to a substrate forming a sealed reaction chamber, the nozzle having a predetermined perimeter shape;
b) Using the first surface modifier port, contacting the reaction chamber with the first surface modifier in a gaseous, or vapor state, for a predetermined period;
c) Using the port for the first reactant, or the port for the first ligand, simultaneously with the step of contacting the reaction chamber with the first surface modifier, contacting the reaction chamber with the reactant in a gaseous, or vapor state, for the same predetermined period, wherein the reactant is configured to react with the first surface modifier, adhering to the substrate and forming a first reaction layer;
d) Using the inert gas port, flushing the reaction chamber;
e) Using the first exhaust port, or the first vacuum port, purging the reaction chamber from excess first surface modifier;
f) Using the second exhaust port, or the second vacuum port, simultaneously with the step of purging the reaction chamber from excess first surface modifier-purging the reaction chamber from excess reactant, thereby etching the first reaction layer;
g) Repeating the steps from the step of contacting the reaction chamber with the first surface modifier, to the step of purging the reaction chamber from excess reactant;
h) Optionally controlling inert gas valve timing, the first exhaust port, the reactant gas port, and the second exhaust port; and
i) Decoupling the substrate from the nozzle.

21. The method of claim 20, wherein the substrate is a wafer.

22. The method of claim 20, wherein the step of coupling the nozzle to the substrate forming the sealed reaction chamber is preceded by a step of heating the substrate to a predetermined temperature.

23. The method of claim 20, wherein the steps of simultaneously contacting the reaction chamber with the first surface modifier and the reactant, is preceded by a step of flushing the reaction chamber with the inert gas for a predetermined period.

24. The method of claim 20, wherein the nozzle size and inner structure is scaled to fit the etching process requirements.
